(19) United States
(12) Patent Application Publication
(10) Pub. No.: US 2026/0045771 A1
(43) Pub. Date: Feb. 12, 2026

(54) QCL DEVICE, EXTERNAL RESONANCE-TYPE QCL MODULE DEVICE, ANALYZER, AND LIGHT IRRADIATION METHOD

(71) Applicant: Mitsubishi Electric Corporation, Tokyo (JP)

(72) Inventor: Kimio SHIGIHARA, Tokyo (JP)

(73) Assignee: Mitsubishi Electric Corporation, Tokyo (JP)

(21) Appl. No.: 19/101,128

(22) PCT Filed: Nov. 15, 2022
(86) PCT No.: PCT/JP2022/042344

§ 371 Date: Feb. 4, 2025

(51) Int. Cl. H01S 5/34; H01S 5/042; H01S 5/343

(52) U.S. Cl. CPC H01S 5/3402; H01S 5/0425; H01S 5/34313; H01S 5/34346

(57) ABSTRACT

A QCL device includes first and second electrodes. When an electric field is applied from the second electrode to the first electrode, first to fourth subbands are formed. The second subband has a higher energy level and a higher electron density than the first subband. Light emits when electrons transition from the second subband to the first subband. The third subband has a lower energy level and the fourth subband has a higher energy level than the second subband. When an electric field is applied from the first electrode to the second electrode, fifth to eighth subbands are formed. The sixth subband has a higher energy level and a higher electron density than the fifth subband. Light emits when electrons transition from the sixth subband to the fifth subband. The seventh subband has a lower energy level and the eighth subband has a higher energy level than the sixth subband.

### FIELD

The present disclosure relates to a QCL device, an external resonance-type QCL module device, an analyzer, and a light irradiation method.

### BACKGROUND

An external resonance-type laser module device using a QCL (Quantum Cascade Laser) device is known as a laser light source. For example, PTL 1 discloses an external resonance-type laser module device including a QCL device and a diffraction reflecting section. The module device includes the QCL device and a MEMS (Micro Electro Mechanical Systems) diffraction grating. The MEMS diffraction grating returns a portion of light emitted from the QCL device back to the QCL device.

### CITATION LIST

### Patent Literature

[PTL 1] JP 2019-036577 A

### Non Patent Literature

[NPL 1] J. Kim, M. Lerttamrab, S. L. Chuang, C. Gmachl, D. L. Sivco, F. Capasso, and A. Y. Cho, “Theoretical and experimental study of optical gain and linewidth enhancement factor of type-I quantum-cascade lasers,” IEEE J. Quantum Electron., Vol. 40, No. 12, pp. 1663-1674, 2004

### SUMMARY

### Technical Problem

However, with the module device described above, a wavelength band that can be returned by the MEMS diffraction grating is wider than a wavelength band of a gain of the QCL device that is generated by current injection. Therefore, there is a problem in that a wavelength band that can be swept as a module device is limited by the wavelength band of the gain of the QCL device generated by current injection.

In order to solve the problem described above, a first object of the present disclosure is to provide a QCL device that enables a wavelength sweep over a wider wavelength band to be performed by providing two different gain bands.

In addition, a second object of the present disclosure is to provide an external resonance-type QCL module device that enables a wavelength sweep over a wider wavelength band to be performed by providing two different gain bands.

Furthermore, a third object of the present disclosure is to provide an analyzer that enables a wavelength sweep over a wider wavelength band to be performed by providing two different gain bands.

Moreover, a fourth object of the present disclosure is to provide a light irradiation method that enables a wavelength sweep over a wider wavelength band to be performed by providing two different gain bands.

### Solution to Problem

The first aspect of the present disclosure is preferably a QCL device, comprising a first electrode, a second electrode, and a core region which is formed between the first electrode and the second electrode and which has a plurality of stages, wherein each stage includes: an active region in which a plurality of alternating barrier layers and well layers are formed and which emits light; and an injector region in which a plurality of alternating barrier layers and well layers are formed and which injects electrons into the active region, when an electric field is applied from the second electrode to the first electrode, a first subband group is formed in the stage, the first subband group includes a first subband, a second subband, a third subband, and a fourth subband, each subband is configured so that the first subband and the second subband have electrons predominantly in the active region, the second subband has a higher energy level and a higher electron density than the first subband, the third subband has a lower energy level than the first subband, the fourth subband has a higher energy level than the second subband, when an electric field is applied from the first electrode to the second electrode, a second subband group is formed in the stage, the second subband group includes a fifth subband, a sixth subband, a seventh subband, and an eighth subband, each subband is configured so that the fifth subband and the sixth subband have electrons predominantly in the active region, the sixth subband has a higher energy level and a higher electron density than the fifth subband, the seventh subband has a lower energy level than the fifth subband, and the eighth subband has a higher energy level than the sixth subband.

The second aspect of the present disclosure is preferably an external resonance-type QCL module device, comprising the QCL device according to the first aspect and a MEMS diffraction grating, wherein the MEMS diffraction grating includes a diffraction reflecting section which diffracts and reflects light emitted from the QCL device, and returns a part of the light back to the QCL device by swinging the diffraction reflecting section.

The third aspect of the present disclosure is preferably an analyzer, comprising: the external resonance-type QCL module device according to the second aspect; a photodetector which detects light emitted from the external resonance-type QCL module device and transmitted through an analyte; and a computing unit which calculates an absorption spectrum based on a detection result of the photodetector.

The fourth aspect of the present disclosure is preferably a light irradiation method using the QCL device according to the first aspect, the light irradiation method comprising: emitting light of a first frequency band by applying an electric field from the second electrode toward the first electrode; and emitting light of a second frequency band by applying an electric field from the first electrode toward the second electrode.

### Advantageous Effects of Invention

According to the first to fourth aspects of the present disclosure, a wavelength sweep over a wider wavelength band can be performed by providing two different gain bands.

### BRIEF DESCRIPTION OF DRAWINGS

FIG. 1 is a perspective view showing a QCL device according to a first embodiment of the present disclosure.

FIG. 2 is a diagram showing a band structure when an electric field is applied from the second electrode toward the first electrode of the QCL device according to the first embodiment of the present disclosure.

FIG. 3 is a diagram showing an existence probability of electrons when an electric field is applied from the second electrode toward the first electrode of the QCL device according to the first embodiment of the present disclosure.

FIG. 4 is a table showing energy levels and electron densities when an electric field is applied from the second electrode toward the first electrode of the QCL device according to the first embodiment of the present disclosure.

FIG. 5 is a diagram showing an existence probability of electrons when an electric field is applied from the first electrode toward the second electrode of the QCL device according to the first embodiment of the present disclosure.

FIG. 6 is a table showing energy levels and electron densities when an electric field is applied from the first electrode toward the second electrode of the QCL device according to the first embodiment of the present disclosure.

FIG. 7 is a first graph showing wavelength dependence of the gain of the QCL device according to the first embodiment of the present disclosure.

FIG. 8 is a second graph showing wavelength dependence of the gain of the QCL device according to the first embodiment of the present disclosure.

FIG. 9 is a diagram showing a band structure when an electric field is applied from the second electrode toward the first electrode of a first modification of the QCL device according to the first embodiment of the present disclosure.

FIG. 10 is a diagram showing an existence probability of electrons when an electric field is applied from the second electrode toward the first electrode of the first modification of the QCL device according to the first embodiment of the present disclosure.

FIG. 11 is a table showing energy levels and electron densities when an electric field is applied from the second electrode toward the first electrode of the first modification of the QCL device according to the first embodiment of the present disclosure.

FIG. 12 is a diagram showing an existence probability of electrons when an electric field is applied from the first electrode toward the second electrode of the first modification of the QCL device according to the first embodiment of the present disclosure.

FIG. 13 is a table showing energy levels and electron densities when an electric field is applied from the first electrode toward the second electrode of the first modification of the QCL device according to the first embodiment of the present disclosure.

FIG. 14 is a graph showing wavelength dependence of the gain of the first modification of the QCL device according to the first embodiment of the present disclosure.

FIG. 15 is a diagram showing a band structure when an electric field is applied from the second electrode toward the first electrode of a second modification of the QCL device according to the first embodiment of the present disclosure.

FIG. 16 is a diagram showing an existence probability of electrons when an electric field is applied from the second electrode toward the first electrode of the second modification of the QCL device according to the first embodiment of the present disclosure.

FIG. 17 is a table showing energy levels and electron densities when an electric field is applied from the second electrode toward the first electrode of the second modification of the QCL device according to the first embodiment of the present disclosure.

FIG. 18 is a diagram showing an existence probability of electrons when an electric field is applied from the first electrode toward the second electrode of the second modification of the QCL device according to the first embodiment of the present disclosure.

FIG. 19 is a table showing energy levels and electron densities when an electric field is applied from the first electrode toward the second electrode of the second modification of the QCL device according to the first embodiment of the present disclosure.

FIG. 20 is a graph showing wavelength dependence of the gain of the first modification of the QCL device according to the first embodiment of the present disclosure.

FIG. 21 is a top view showing an external resonance-type QCL module device according to a second embodiment of the present disclosure.

FIG. 22 is a sectional view showing the external resonance-type QCL module device according to the second embodiment of the present disclosure.

FIG. 23 is a diagram showing a drive method of the MEMS diffraction grating and the QCL device according to the second embodiment of the present disclosure.

FIG. 24 is a diagram showing a modification of a drive method of the external resonance-type QCL module device according to the second embodiment of the present disclosure.

FIG. 25 is a diagram showing an analyzer according to a third embodiment of the present disclosure.

### DESCRIPTION OF EMBODIMENTS

### First Embodiment

### Configuration of QCL Device According to First Embodiment

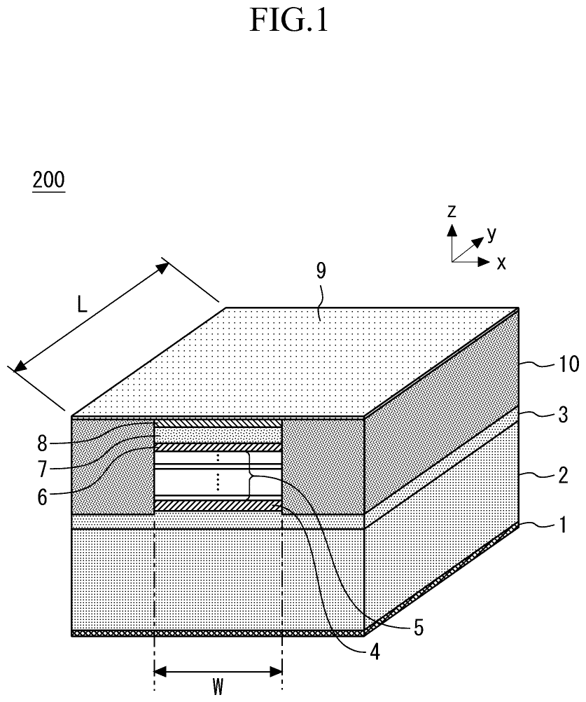

FIG. 1 is a perspective view showing a QCL device according to a first embodiment of the present disclosure. A QCL device 200 is an embedded ridge-type QCL device with a resonator length L and a ridge width W.

The QCL device 200 includes a first electrode 1. A substrate 2 is bonded on top of the first electrode 1. For example, the substrate 2 is an n-type InP substrate. A buffer layer 3 is bonded on top of the substrate 2. For example, the buffer layer 3 is an n-type InP layer with a layer thickness of 1.0 m.

A light confinement layer 4 is bonded on top of the buffer layer 3. For example, the light confinement layer 4 is an n-type Ga0.47In0.53As (hereinafter, referred to as GaInAs) layer with a layer thickness of 230 nm. A core region 5 is bonded on top of the light confinement layer 4. For example, the core region 5 is a core region constituted of 35 stages. Details of the core region 5 will be provided later.

A light confinement layer 6 is bonded on top of the core region 5. For example, the light confinement layer 6 is an n-type GaInAs layer with a layer thickness of 230 nm. A cladding layer 7 is bonded on top of the light confinement layer 6. For example, the cladding layer 7 is an n-type InP layer with a layer thickness of 3.5 m. A contact layer 8 is bonded on top of the cladding layer 7. For example, the contact layer 8 is an n-type GaInAs layer with a layer thickness of 500 nm.

A second electrode 9 is bonded on top of the contact layer 8. A current blocking layer 10 is present in a region that is between the second electrode 9 and the buffer layer 3 and that surrounds the light confinement layer 4, the core region 5, the light confinement layer 6, the cladding layer 7, and the contact layer 8. For example, the current blocking layer 10 is a Fe-doped InP layer.

Conventional QCL devices have only been used to perform current injection in one direction, from the first electrode 1 to the second electrode 9. However, the QCL device according to the present embodiment performs current injection from the second electrode 9 to the first electrode 1 in addition to performing current injection from the first electrode 1 to the second electrode 9. In other words, two different gain bands are provided by injecting current from two directions.

### Analysis of Laser Characteristics in QCL Device According to First Embodiment

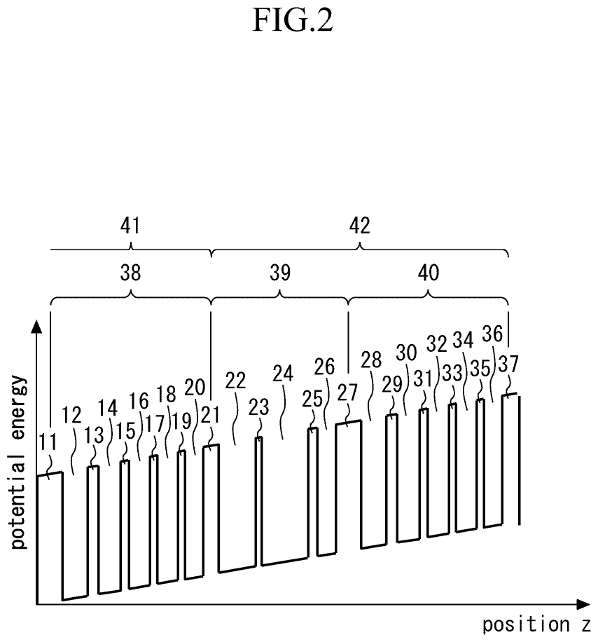

FIG. 2 is a diagram showing a band structure when an electric field is applied from the second electrode toward the first electrode of the QCL device according to the first embodiment of the present disclosure. In this case, a band structure of a conduction band is shown in which an injector region of a stage 41 that is one of the stages included in the core region 5 has been added to a stage 42 that is a stage adjacent to the stage 41. In addition, a strength of the applied electric field is 5.0×10⁶ V/m.

In the QCL device according to the present embodiment, the core region 5 is made up of 35 stages. In other words, a same stage is provided consecutively 35 times. One stage is made up of one active region and one injector region. A description of the active region and the injector region will be provided later.

The stage 42 includes an active region 39. The active region 39 is a region that emits light when electrons transition between subbands formed within the active region. In addition, the active region 39 is constructed by bonding barrier layers and well layers to each other in an alternating manner. Here, an aspect in which the number of wells is three is shown as an example.

The active region 39 includes a barrier layer 21. For example, the barrier layer 21 is an undoped Al_{0.48}In_{0.52}As (hereafter referred to as AlInAs) layer with a layer thickness of 2.4 nm. A well layer 22 is adjacent to the barrier layer 21. For example, the well layer 22 is an undoped GaInAs layer with a film thickness of 6.5 nm. A barrier layer 23 is adjacent to the well layer 22. For example, the barrier layer 23 is an undoped AlInAs layer with a layer thickness of 0.9 nm. A well layer 24 is adjacent to the barrier layer 23. For example, the well layer 24 is an undoped GaInAs layer with a film thickness of 6.4 nm. A barrier layer 25 is adjacent to the well layer 24. For example, the barrier layer 25 is an undoped AlInAs layer with a layer thickness of 1.5 nm. A well layer 26 is adjacent to the barrier layer 25. For example, the well layer 26 is an undoped GaInAs layer with a film thickness of 3.4 nm. A barrier layer 27 is adjacent to the well layer 26. For example, the barrier layer 27 is an undoped AlInAs layer with a layer thickness of 4.0 nm.

In addition, the stage 42 includes an injector region 40. The injector region 40 is a region that injects electrons into an active region and is adjacent to the active region 39. In addition, the injector region 40 is constructed by bonding barrier layers and well layers to each other in an alternating manner. In this case, an aspect in which the number of wells is five is shown as an example.

The injector region 40 includes the barrier layer 27 described above. A well layer 28 is adjacent to the barrier layer 27. For example, the well layer 28 is an undoped GaInAs layer with a film thickness of 4.1 nm. A barrier layer 29 is adjacent to the well layer 28. For example, the barrier layer 29 is an undoped AlInAs layer with a layer thickness of 1.7 nm. A well layer 30 is adjacent to the barrier layer 29. For example, the well layer 30 is an undoped GaInAs layer with a film thickness of 3.7 nm. A barrier layer 31 is adjacent to the well layer 30. For example, the barrier layer 31 is an undoped AlInAs layer with a layer thickness of 1.2 nm.

A well layer 32 is adjacent to the barrier layer 31. For example, the well layer 32 is a GaInAs layer doped to an n-type (hereinafter, referred to as an n-type GaInAs layer) with a film thickness of 3.4 nm. A barrier layer 33 is adjacent to the well layer 32. For example, the barrier layer 33 is an n-type AlInAs layer with a layer thickness of 1.1 nm. A well layer 34 is adjacent to the barrier layer 33. For example, the well layer 34 is an n-type GaInAs layer with a film thickness of 3.4 nm.

A barrier layer 35 is adjacent to the well layer 34. For example, the barrier layer 35 is an undoped AlInAs layer with a layer thickness of 1.1 nm. A well layer 36 is adjacent to the barrier layer 35. For example, the well layer 36 is an undoped GaInAs layer with a film thickness of 2.9 nm. A barrier layer 37 is adjacent to the well layer 36. For example, the barrier layer 37 is an undoped AlInAs layer with a layer thickness of 2.4 nm.

Furthermore, the stage 42 is adjacent to an injector region 38 of the stage 41. The injector region 38 is constructed by bonding barrier layers and well layers to each other in an alternating manner. In this case, an aspect in which the number of wells is five is shown as an example.

The injector region 38 includes a barrier layer 11. For example, the barrier layer 11 is an undoped AlInAs layer with a layer thickness of 4.0 nm. A well layer 12 is adjacent to the barrier layer 11. For example, the well layer 12 is an undoped GaInAs layer with a film thickness of 4.1 nm. A barrier layer 13 is adjacent to the well layer 12. For example, the barrier layer 13 is an undoped AlInAs layer with a layer thickness of 1.7 nm. A well layer 14 is adjacent to the barrier layer 13. For example, the well layer 14 is an undoped GaInAs layer with a film thickness of 3.7 nm. A barrier layer 15 is adjacent to the well layer 14. For example, the barrier layer 15 is an undoped AlInAs layer with a layer thickness of 1.2 nm.

A well layer 16 is adjacent to the barrier layer 15. For example, the well layer 16 is an n-type GaInAs layer with a film thickness of 3.4 nm. A barrier layer 17 is adjacent to the well layer 16. For example, the barrier layer 17 is an n-type AlInAs layer with a layer thickness of 1.1 nm. A well layer 18 is adjacent to the barrier layer 17. For example, the well layer 18 is an n-type GaInAs layer with a film thickness of 3.4 nm.

A barrier layer 19 is adjacent to the well layer 18. For example, the barrier layer 19 is an undoped AlInAs layer with a layer thickness of 1.1 nm. A well layer 20 is adjacent to the barrier layer 19. For example, the well layer 20 is an undoped GaInAs layer with a film thickness of 2.9 nm. The barrier layer 21 described earlier is adjacent to the well layer 20.

A doping amount of n-type AlInAs layers in the injector regions 38 and 40 is, for example, 2.5×10¹⁷ cm⁻³.

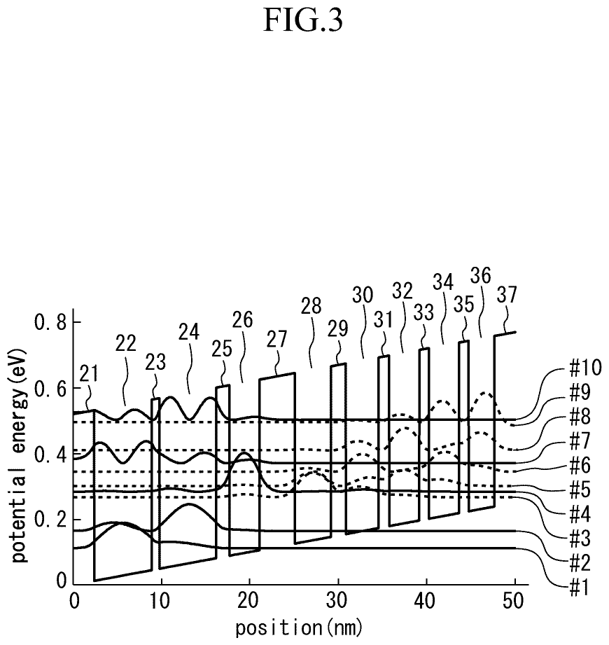

FIG. 3 is a diagram showing an existence probability of electrons when an electric field is applied from the second electrode toward the first electrode of the QCL device according to the first embodiment of the present disclosure. FIG. 3 shows a square of a wave function at each energy level in the stage 42. In other words, FIG. 3 shows a degree of the existence probability of electrons at each energy level.

As described earlier, in the QCL device according to the present embodiment, the core region 5 is made up of 35 stages. In other words, a same stage is provided consecutively 35 times. Therefore, when analyzing laser characteristics, analyzing laser characteristics with respect to one stage will suffice. Subsequent analyses were performed based on NPL 1.

In this case, there are 10 different energy levels allowed in the stage 42. The 10 energy levels are numbered from #1 to #10, starting with a lowest energy level. In addition, each energy level is shown by a solid line if the electrons are mainly present in the active region 39 and by a dashed line if the electrons are mainly present in the injector region 40. The levels where electrons are mainly present in the active region 39 are #1, #2, #4, #7, and #10. The levels where electrons are mainly present in the injector region 40 are #3, #5, #6, #8, and #9.

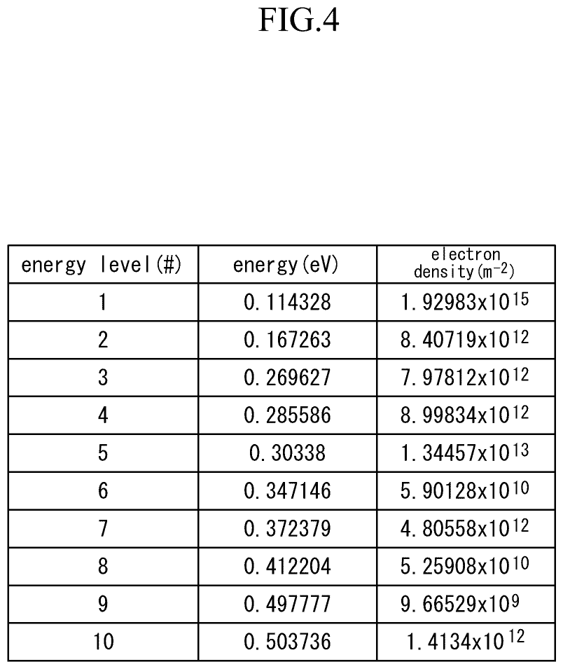

FIG. 4 is a table showing energy levels and electron densities when an electric field is applied from the second electrode toward the first electrode of the QCL device according to the first embodiment of the present disclosure.

There are three conditions necessary for laser oscillation to occur in a QCL device. The first is that a population inversion has occurred in the active region 39. In other words, in energy levels where electrons are mainly present in the active region, there need only be an upper energy level with a higher electron density than an electron density of a lower energy level. Accordingly, since electronic transitions from the upper energy level to the lower energy level are facilitated, laser oscillation is also facilitated.

The second is that there is a lower energy level than the lower energy level described above. Accordingly, electrons can be pulled from the lower energy level.

The third is that there is a higher energy level than the higher energy level described above. Accordingly, electrons can be injected into the higher energy level.

Laser oscillation can occur when the above three conditions are satisfied by the energy levels allowed in the stage and the electron densities of the energy levels. In consideration thereof, the three conditions will be confirmed with respect to the energy levels and the electron densities shown in FIG. 4.

In energy levels where electrons are mainly present in the active region 39, there is an upper energy level #4 with a higher electron density than an electron density of a lower energy level #2. In addition, there is an energy level #1 that is a lower energy level than the lower energy level #2. Furthermore, there are energy levels #5, #6, #7, #8, #9, and #10 that are higher energy levels than the higher energy level #4.

As described above, the energy levels and the electron densities shown in FIG. 4 satisfy the three conditions necessary for laser oscillation. Therefore, laser oscillation can occur when an electric field is applied from the second electrode toward the first electrode of the QCL device according to the present embodiment.

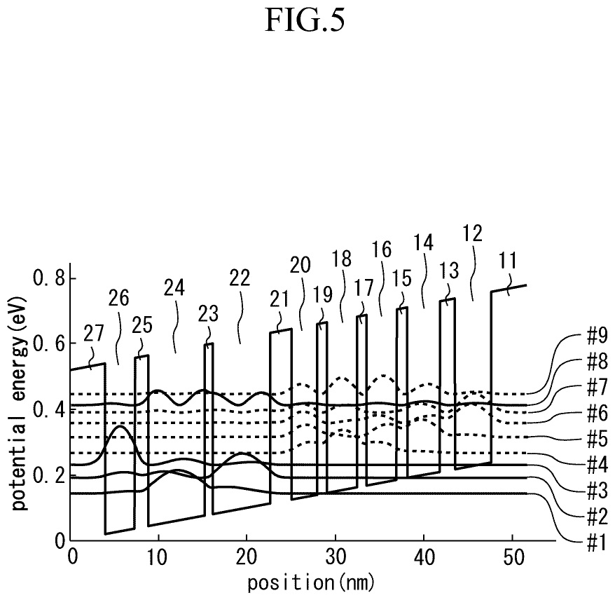

FIG. 5 is a diagram showing an existence probability of electrons when an electric field is applied from the first electrode toward the second electrode of the QCL device according to the first embodiment of the present disclosure. FIG. 5 shows a square of a wave function at each energy level in the stage 42. For convenience of calculation, an orientation of each layer has been reversed so that potential energy increases toward the right. In addition, the strength of the applied electric field is 5.0×10⁶ V/m which is the same as in FIGS. 2 and 3.

In this case, there are nine different energy levels allowed in the stage 42. The nine energy levels are numbered from #1 to #9, starting with a lowest energy level. In addition, each energy level is shown by a solid line if the electrons are mainly present in the active region 39 and by a dashed line if the electrons are mainly present in the injector region 40. The levels where electrons are mainly present in the active region 39 are #1, #2, #3, and #8. The levels where electrons are mainly present in the injector region 40 are #4, #5, #6, #7, and #9.

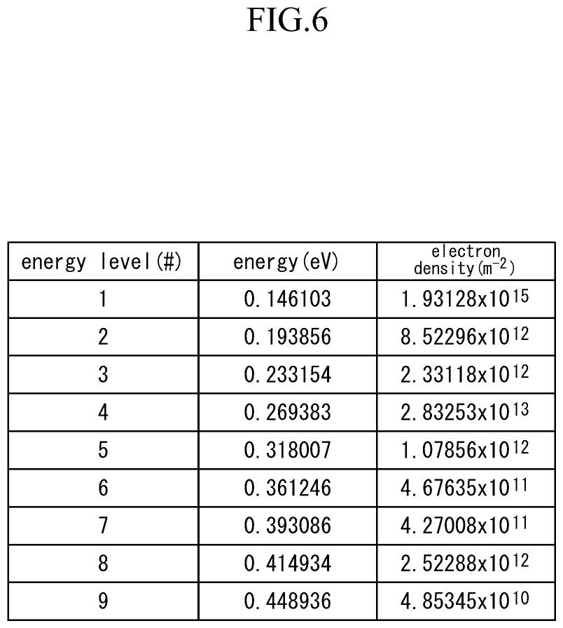

FIG. 6 is a table showing energy levels and electron densities when an electric field is applied from the first electrode toward the second electrode of the QCL device according to the first embodiment of the present disclosure.

The three conditions will be confirmed with respect to the energy levels and the electron densities shown in FIG. 6. In energy levels where electrons are mainly present in the active region 39, there is an upper energy level #8 with a higher electron density than an electron density of a lower energy level #3. In addition, there are energy levels #1 and #2 that are lower energy levels than the lower energy level #3. Furthermore, there is an energy level #9 that is a higher energy level than the higher energy level #8.

As described above, the energy levels and the electron densities shown in FIG. 6 satisfy the three conditions necessary for laser oscillation. Therefore, laser oscillation can occur when an electric field is applied from the first electrode toward the second electrode of the QCL device according to the present embodiment.

As described above, in the QCL device according to the present embodiment, laser oscillation can occur whether current is injected from the first electrode 1 toward the second electrode 9 or from the second electrode 9 toward the first electrode 1. In other words, two different gain bands can be provided by injecting current into the QCL device from two directions.

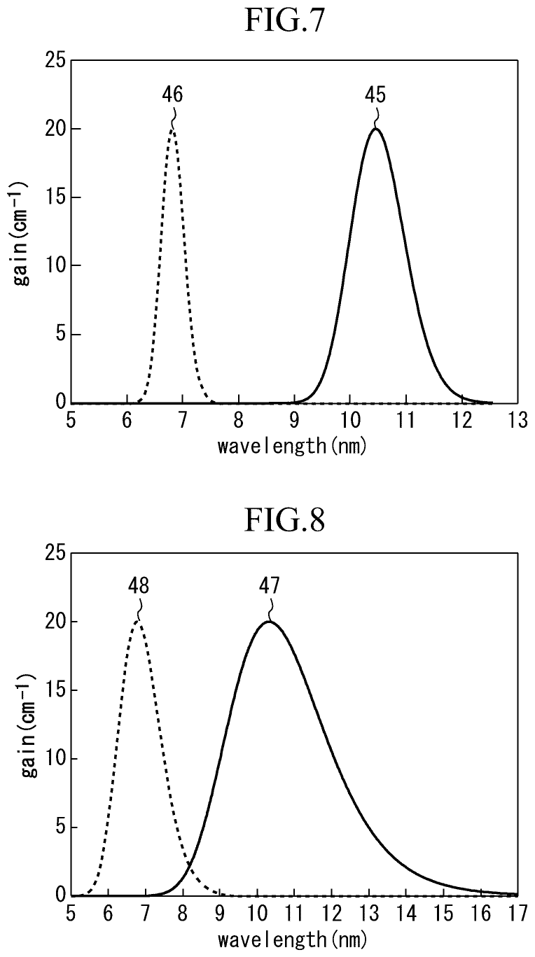

FIG. 7 is a first graph showing wavelength dependence of the gain of the QCL device according to the first embodiment of the present disclosure. In this case, gains when using an embedded ridge-type QCL device with a resonator length L of 1.36 mm and a ridge width of 14 μm are shown. A gain 45 when an electric field is applied from the second electrode 9 toward the first electrode 1 and a current of 137 mA is injected is shown by a solid line. A gain 46 when an electric field is applied from the first electrode 1 toward the second electrode 9 and a current of 326 mA is injected is shown by a dashed line. The line width Γ is 5.5 meV.

A peak wavelength of the gain 45 is 10.45 μm and a bandwidth at half-maximum is 1.13 μm. On the other hand, a peak wavelength of the gain 46 is 6.82 μm and a bandwidth at half-maximum is 0.48 μm.

As described above, two different gain bands can be provided by injecting current into the QCL device from two directions.

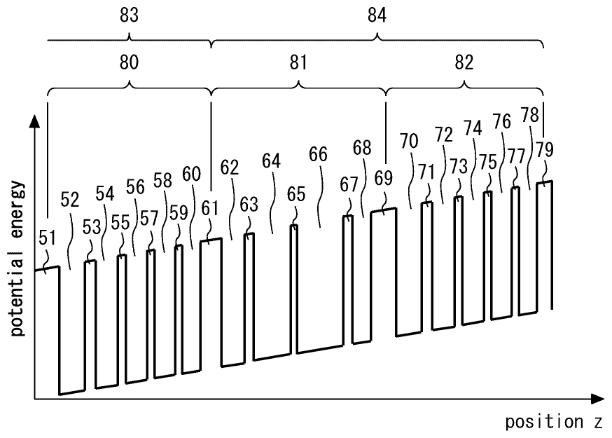

FIG. 8 is a second graph showing wavelength dependence of the gain of the QCL device according to the first embodiment of the present disclosure. In the gain shown in FIG. 7, a line width Γ is set to 5.5 meV by setting a doping concentration in the injector region to 2.5×10¹⁷ cm⁻³. However, an impurity scattering time in subbands can be reduced by further increasing the doping concentration. Accordingly, since the line width Γ can be increased, a gain band can be broadened while hardly changing the peak gain wavelength.

Here, a case where the line width Γ is set to 15 meV is shown as an example showing a result of broadening the gain band. A gain 47 when an electric field is applied from the second electrode 9 toward the first electrode 1 and a current of 372 mA is injected is shown by a solid line. A gain 48 when an electric field is applied from the first electrode 1 toward the second electrode 9 and a current of 887 mA is injected is shown by a dashed line. The line width Γ is 5.5 meV.

A peak wavelength of the gain 47 is 10.31 μm and a bandwidth at half-maximum is 3.06 μm. On the other hand, a peak wavelength of the gain 48 is 6.78 μm and a bandwidth at half-maximum is 1.31 μm.

As described above, by further increasing the doping concentration and increasing the line width Γ, the gain band can be broadened while hardly changing the peak gain wavelength. When this method is applied to an external resonance-type QCL module device to be described later, if the loss of an external resonator is less than 2.1 cm⁻¹, a wavelength sweep can be performed over a wide wavelength range from 5.8 μm to 14.0 μm.

### Analysis of Laser Characteristics in First Modification of QCL Device According to First Embodiment

FIG. 9 is a diagram showing a band structure when an electric field is applied from the second electrode toward the first electrode of a first modification of the QCL device according to the first embodiment of the present disclosure. In this case, a band structure of a conduction band is shown in which an injector region of a stage 83 that is one of the stages included in the core region 5 has been added to a stage 84 that is a stage adjacent to the stage 83. In addition, a strength of the applied electric field is 5.0×10⁶ V/m. An active region 81 included in the first modification of the QCL device differs from the active region 39 in that the number of wells is four.

The stage 84 includes the active region 81. The active region 81 includes a barrier layer 61. For example, the barrier layer 61 is an undoped AlInAs layer with a layer thickness of 3.5 nm. A well layer 62 is adjacent to the barrier layer 61. For example, the well layer 62 is an undoped GaInAs layer with a film thickness of 3.0 nm. A barrier layer 63 is adjacent to the well layer 62. For example, the barrier layer 63 is an undoped AlInAs layer with a layer thickness of 1.5 nm. A well layer 64 is adjacent to the barrier layer 63. For example, the well layer 64 is an undoped GaInAs layer with a film thickness of 6.5 nm. A barrier layer 65 is adjacent to the well layer 64. For example, the barrier layer 65 is an undoped AlInAs layer with a layer thickness of 0.9 nm. A well layer 66 is adjacent to the barrier layer 65. For example, the well layer 66 is an undoped GaInAs layer with a film thickness of 6.5 nm. A barrier layer 67 is adjacent to the well layer 66. For example, the barrier layer 67 is an undoped AlInAs layer with a layer thickness of 0.9 nm. A well layer 68 is adjacent to the barrier layer 67. For example, the well layer 68 is an undoped GaInAs layer with a film thickness of 5.4 nm. A barrier layer 69 is adjacent to the well layer 68. For example, the barrier layer 69 is an undoped AlInAs layer with a layer thickness of 2.4 nm.

In addition, the stage 84 includes an injector region 82. The injector region 82 includes the barrier layer 69 described above. A well layer 70 is adjacent to the barrier layer 69. For example, the well layer 70 is an undoped GalInAs layer with a film thickness of 2.9 nm. A barrier layer 71 is adjacent to the well layer 70. For example, the barrier layer 71 is an undoped AlInAs layer with a layer thickness of 1.1 nm.

A well layer 72 is adjacent to the barrier layer 71. For example, the well layer 72 is an n-type GaInAs layer with a film thickness of 3.4 nm. A barrier layer 73 is adjacent to the well layer 72. For example, the barrier layer 73 is an n-type AlInAs layer with a layer thickness of 1.1 nm. A well layer 74 is adjacent to the barrier layer 73. For example, the well layer 74 is an n-type GaInAs layer with a film thickness of 3.4 nm.

A barrier layer 75 is adjacent to the well layer 74. For example, the barrier layer 75 is an undoped AlInAs layer with a layer thickness of 1.2 nm. A well layer 76 is adjacent to the barrier layer 75. For example, the well layer 76 is an undoped GaInAs layer with a film thickness of 3.7 nm. A barrier layer 77 is adjacent to the well layer 76. For example, the barrier layer 77 is an undoped AlInAs layer with a layer thickness of 1.7 nm. A well layer 78 is adjacent to the barrier layer 77. For example, the well layer 78 is an undoped GaInAs layer with a film thickness of 4.1 nm. A barrier layer 79 is adjacent to the well layer 78. For example, the barrier layer 79 is an undoped AlInAs layer with a layer thickness of 3.5 nm.

In addition, the stage 84 is adjacent to an injector region 80 of the stage 83. The injector region 80 includes a barrier layer 51. For example, the barrier layer 51 is an undoped AlInAs layer with a layer thickness of 2.4 nm. A well layer 52 is adjacent to the barrier layer 51. For example, the well layer 52 is an undoped GaInAs layer with a film thickness of 2.9 nm. A barrier layer 53 is adjacent to the well layer 52. For example, the barrier layer 53 is an undoped AlInAs layer with a layer thickness of 1.1 nm.

A well layer 54 is adjacent to the barrier layer 53. For example, the well layer 54 is an n-type GaInAs layer with a film thickness of 3.4 nm. A barrier layer 55 is adjacent to the well layer 54. For example, the barrier layer 55 is an n-type AlInAs layer with a layer thickness of 1.1 nm. A well layer 56 is adjacent to the barrier layer 55. For example, the well layer 56 is an n-type GaInAs layer with a film thickness of 3.4 nm.

A barrier layer 57 is adjacent to the well layer 56. For example, the barrier layer 57 is an undoped AlInAs layer with a layer thickness of 1.2 nm. A well layer 58 is adjacent to the barrier layer 57. For example, the well layer 58 is an undoped GaInAs layer with a film thickness of 3.7 nm. A barrier layer 59 is adjacent to the well layer 58. For example, the barrier layer 59 is an undoped AlInAs layer with a layer thickness of 1.7 nm. A well layer 60 is adjacent to the barrier layer 59. For example, the well layer 60 is an undoped GaInAs layer with a film thickness of 4.1 nm. The barrier layer 61 described earlier is adjacent to the well layer 60.

A doping amount of n-type AlInAs layers in the injector regions 80 and 82 is, for example, 2.5×10¹⁷ cm⁻³.

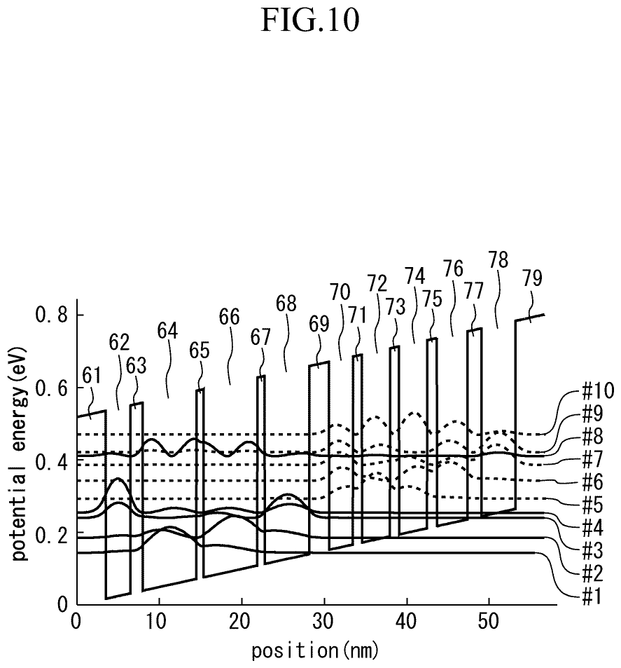

FIG. 10 is a diagram showing an existence probability of electrons when an electric field is applied from the second electrode toward the first electrode of the first modification of the QCL device according to the first embodiment of the present disclosure. FIG. 10 shows a square of a wave function at each energy level in the stage 84. In other words, FIG. 10 shows a degree of the existence probability of electrons at each energy level.

In this case, there are 10 different energy levels allowed in the stage 84. The 10 energy levels are numbered from #1 to #10, starting with a lowest energy level. In addition, each energy level is shown by a solid line if the electrons are mainly present in the active region 81 and by a dashed line if the electrons are mainly present in the injector region 82. The levels where electrons are mainly present in the active region 81 are #1, #2, #3, #4, and #8. The levels where electrons are mainly present in the injector region 82 are #5, #6, #7, #9, and #10.

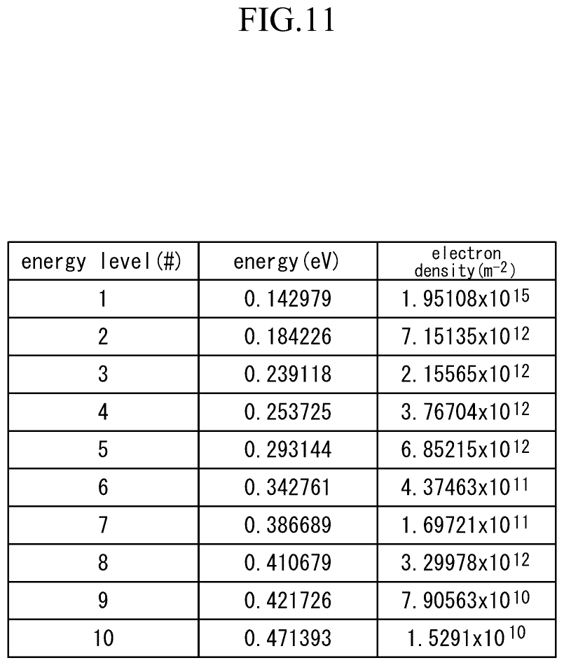

FIG. 11 is a table showing energy levels and electron densities when an electric field is applied from the second electrode toward the first electrode of the first modification of the QCL device according to the first embodiment of the present disclosure. Laser oscillation can occur when the three conditions described earlier are satisfied by the energy levels allowed in the stage and the electron densities of the energy levels. In consideration thereof, the three conditions will be confirmed with respect to the energy levels and the electron densities shown in FIG. 11.

In energy levels where electrons are mainly present in the active region 81, there is an upper energy level #8 with a higher electron density than an electron density of a lower energy level #3. In addition, there are energy levels #1 and #2 that are lower energy levels than the lower energy level #3. Furthermore, there are energy levels #9 and #10 that are higher energy levels than the higher energy level #8.

As described above, the energy levels and the electron densities shown in FIG. 11 satisfy the three conditions necessary for laser oscillation. Therefore, laser oscillation can occur when an electric field is applied from the second electrode toward the first electrode of the first modification of the QCL device according to the present embodiment.

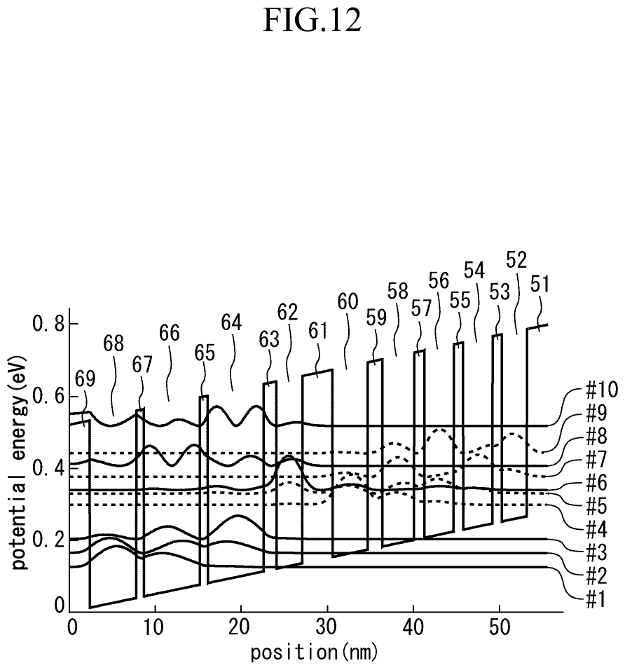

FIG. 12 is a diagram showing an existence probability of electrons when an electric field is applied from the first electrode toward the second electrode of the first modification of the QCL device according to the first embodiment of the present disclosure. FIG. 12 shows a square of a wave function at each energy level in the stage 84. For convenience of calculation, an orientation of each layer has been reversed so that potential energy increases toward the right. In addition, the strength of the applied electric field is 5.0×10⁶ V/m which is the same as in FIGS. 10 and 11.

In this case, there are 10 different energy levels allowed in the stage 84. The 10 energy levels are numbered from #1 to #10, starting with a lowest energy level. In addition, each energy level is shown by a solid line if the electrons are mainly present in the active region 81 and by a dashed line if the electrons are mainly present in the injector region 82. The levels where electrons are mainly present in the active region 81 are #1, #2, #3, #6, #8, and #10. The levels where electrons are mainly present in the injector region 82 are #4, #5, #7, and #9.

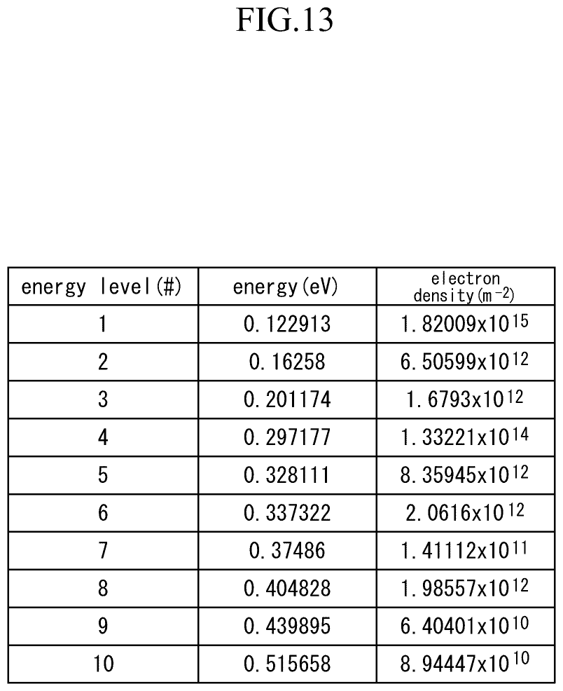

FIG. 13 is a table showing energy levels and electron densities when an electric field is applied from the first electrode toward the second electrode of the first modification of the QCL device according to the first embodiment of the present disclosure.

The three conditions will be confirmed with respect to the energy levels and the electron densities shown in FIG. 13. In energy levels where electrons are mainly present in the active region 81, there is an upper energy level #6 with a higher electron density than an electron density of a lower energy level #3. In addition, there are energy levels #1 and #2 that are lower energy levels than the lower energy level #3. Furthermore, there are energy levels #7, #8, #9, and #10 that are higher energy levels than the higher energy level #6.

As described above, the energy levels and the electron densities shown in FIG. 13 satisfy the three conditions necessary for laser oscillation. Therefore, laser oscillation can occur when an electric field is applied from the first electrode toward the second electrode of the first modification of the QCL device according to the present embodiment.

As described above, in the first modification of the QCL device according to the present embodiment, laser oscillation can occur whether current is injected from the first electrode 1 toward the second electrode 9 or from the second electrode 9 toward the first electrode 1. In other words, two different gain bands can be provided by injecting current into the QCL device from two directions.

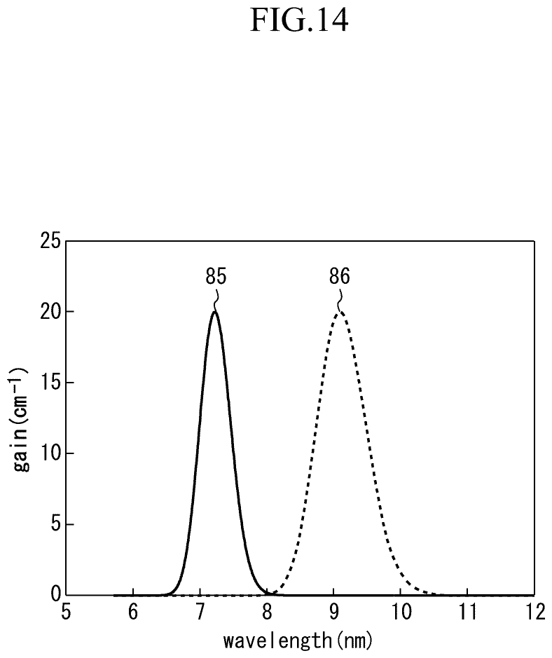

FIG. 14 is a graph showing wavelength dependence of the gain of the first modification of the QCL device according to the first embodiment of the present disclosure. In this case, gains when using an embedded ridge-type QCL device with a resonator length L of 1.36 mm and a ridge width of 14 μm are shown. A gain 85 when an electric field is applied from the second electrode 9 toward the first electrode 1 and a current of 1652 mA is injected is shown by a solid line. A gain 86 when an electric field is applied from the first electrode 1 toward the second electrode 9 and a current of 407 mA is injected is shown by a dashed line.

A peak wavelength of the gain 85 is 7.22 μm and a bandwidth at half-maximum is 0.54 μm. On the other hand, a peak wavelength of the gain 86 is 9.09 μm and a bandwidth at half-maximum is 0.85 μm.

As described above, two different gain bands can be provided by injecting current into the QCL device from two directions.

### Analysis of Laser Characteristics in Second Modification of QCL Device According to First Embodiment

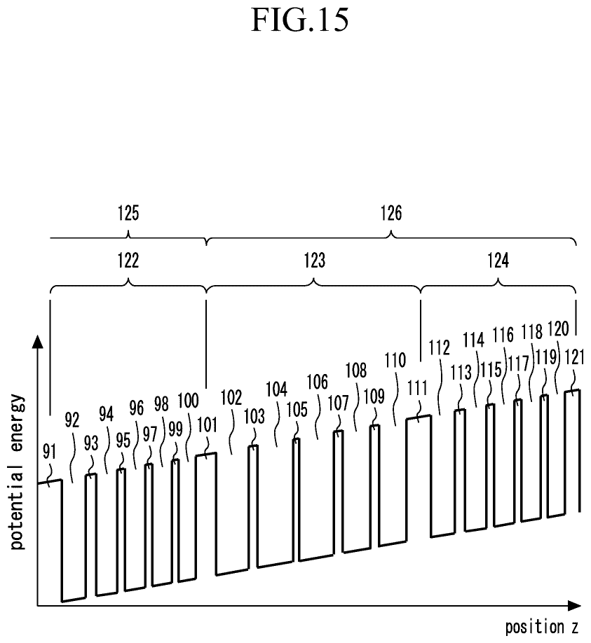

FIG. 15 is a diagram showing a band structure when an electric field is applied from the second electrode toward the first electrode of a second modification of the QCL device according to the first embodiment of the present disclosure. In this case, a band structure of a conduction band is shown in which an injector region of a stage 125 that is one of the stages included in the core region 5 has been added to a stage 126 that is a stage adjacent to the stage 125. In addition, a strength of the applied electric field is 5.0×10⁶ V/m. An active region 123 included in the second modification of the QCL device differs from the active region 39 in that the number of wells is five.

The stage 126 includes the active region 123. The active region 123 includes a barrier layer 101. For example, the barrier layer 101 is an undoped AlInAs layer with a layer thickness of 2.4 nm. A well layer 102 is adjacent to the barrier layer 101. For example, the well layer 102 is an undoped GaInAs layer with a film thickness of 5.0 nm. A barrier layer 103 is adjacent to the well layer 102. For example, the barrier layer 103 is an undoped AlInAs layer with a layer thickness of 0.9 nm. A well layer 104 is adjacent to the barrier layer 103. For example, the well layer 104 is an undoped GaInAs layer with a film thickness of 6.0 nm. A barrier layer 105 is adjacent to the well layer 104. For example, the barrier layer 105 is an undoped AlInAs layer with a layer thickness of 0.9 nm. A well layer 106 is adjacent to the barrier layer 105. For example, the well layer 106 is an undoped GaInAs layer with a film thickness of 6.0 nm. A barrier layer 107 is adjacent to the well layer 106. For example, the barrier layer 107 is an undoped AlInAs layer with a layer thickness of 0.8 nm. A well layer 108 is adjacent to the barrier layer 107. For example, the well layer 108 is an undoped GaInAs layer with a film thickness of 4.5 nm. A barrier layer 109 is adjacent to the well layer 108. For example, the barrier layer 109 is an undoped AlInAs layer with a layer thickness of 0.8 nm. A well layer 110 is adjacent to the barrier layer 109. For example, the well layer 110 is an undoped GaInAs layer with a film thickness of 3.0 nm. A barrier layer 111 is adjacent to the well layer 110. For example, the barrier layer 111 is an undoped AlInAs layer with a layer thickness of 3.5 nm.

In addition, the stage 126 includes an injector region 124. The injector region 124 includes the barrier layer 111 described above. A well layer 112 is adjacent to the barrier layer 111. For example, the well layer 112 is an undoped GaInAs layer with a film thickness of 4.1 nm. A barrier layer 113 is adjacent to the well layer 112. For example, the barrier layer 113 is an undoped AlInAs layer with a layer thickness of 1.7 nm. A well layer 114 is adjacent to the barrier layer 113. For example, the well layer 114 is an undoped GaInAs layer with a film thickness of 3.7 nm. A barrier layer 115 is adjacent to the well layer 114. For example, the barrier layer 115 is an undoped AlInAs layer with a layer thickness of 1.2 nm.

A well layer 116 is adjacent to the barrier layer 115. For example, the well layer 116 is an n-type GaInAs layer with a film thickness of 3.4 nm. A barrier layer 117 is adjacent to the well layer 116. For example, the barrier layer 117 is an n-type AlInAs layer with a layer thickness of 1.1 nm. A well layer 118 is adjacent to the barrier layer 117. For example, the well layer 118 is an n-type GaInAs layer with a film thickness of 3.4 nm.

A barrier layer 119 is adjacent to the well layer 118. For example, the barrier layer 119 is an undoped AlInAs layer with a layer thickness of 1.1 nm. A well layer 120 is adjacent to the barrier layer 119. For example, the well layer 120 is an undoped GaInAs layer with a film thickness of 2.9 nm. A barrier layer 121 is adjacent to the well layer 120. For example, the barrier layer 121 is an undoped AlInAs layer with a layer thickness of 2.4 nm.

In addition, the stage 126 is adjacent to an injector region 122 of the stage 125. The injector region 122 includes a barrier layer 91. For example, the barrier layer 91 is an undoped AlInAs layer with a layer thickness of 3.5 nm. A well layer 92 is adjacent to the barrier layer 91. For example, the well layer 92 is an undoped GaInAs layer with a film thickness of 4.1 nm. A barrier layer 93 is adjacent to the well layer 92. For example, the barrier layer 93 is an undoped AlInAs layer with a layer thickness of 1.7 nm. A well layer 94 is adjacent to the barrier layer 93. For example, the well layer 94 is an undoped GaInAs layer with a film thickness of 3.7 nm. A barrier layer 95 is adjacent to the well layer 94. For example, the barrier layer 95 is an undoped AlInAs layer with a layer thickness of 1.2 nm.

A well layer 96 is adjacent to the barrier layer 95. For example, the well layer 96 is an n-type GaInAs layer with a film thickness of 3.4 nm. A barrier layer 97 is adjacent to the well layer 96. For example, the barrier layer 97 is an n-type AlInAs layer with a layer thickness of 1.1 nm. A well layer 98 is adjacent to the barrier layer 97. For example, the well layer 98 is an n-type GaInAs layer with a film thickness of 3.7 nm.

A barrier layer 99 is adjacent to the well layer 98. For example, the barrier layer 99 is an undoped AlInAs layer with a layer thickness of 1.1 nm. A well layer 100 is adjacent to the barrier layer 99. For example, the well layer 100 is an undoped GaInAs layer with a film thickness of 2.9 nm. The barrier layer 101 described earlier is adjacent to the well layer 100.

A doping amount of n-type AlInAs layers in the injector regions 122 and 124 is, for example, 2.5×10¹⁷ cm⁻³.

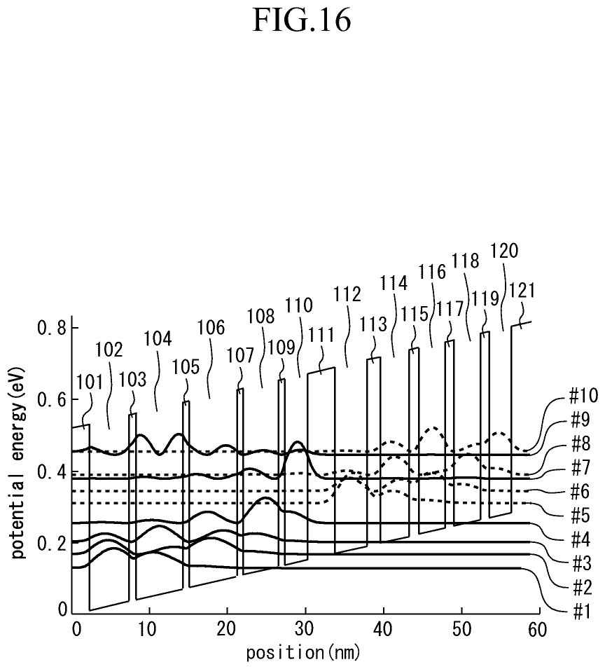

FIG. 16 is a diagram showing an existence probability of electrons when an electric field is applied from the second electrode toward the first electrode of the second modification of the QCL device according to the first embodiment of the present disclosure. FIG. 16 shows a square of a wave function at each energy level in the stage 126. In other words, FIG. 16 shows a degree of the existence probability of electrons at each energy level.

In this case, there are 10 different energy levels allowed in the stage 126. The 10 energy levels are numbered from #1 to #10, starting with a lowest energy level. In addition, each energy level is shown by a solid line if the electrons are mainly present in the active region 123 and by a dashed line if the electrons are mainly present in the injector region 124. The levels where electrons are mainly present in the active region 123 are #1, #2, #3, #4, #7, and #9. The levels where electrons are mainly present in the injector region 124 are #5, #6, #8, and #10.

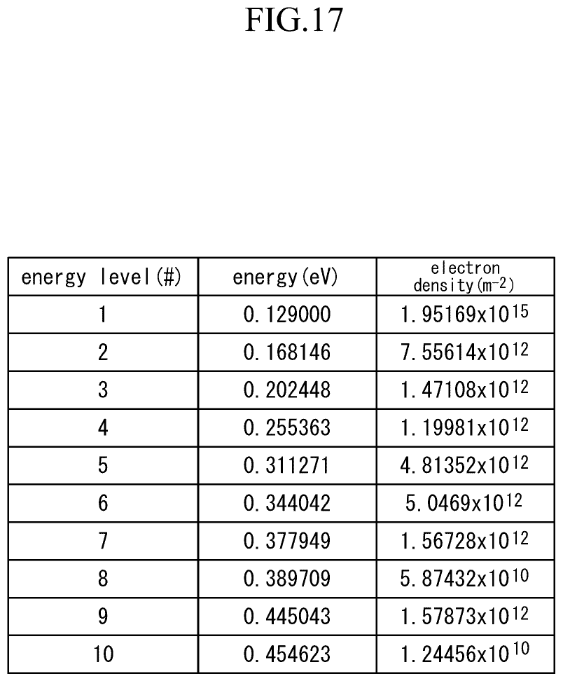

FIG. 17 is a table showing energy levels and electron densities when an electric field is applied from the second electrode toward the first electrode of the second modification of the QCL device according to the first embodiment of the present disclosure. Laser oscillation can occur when the three conditions described earlier are satisfied by the energy levels allowed in the stage and the electron densities of the energy levels. In consideration thereof, the three conditions will be confirmed with respect to the energy levels and the electron densities shown in FIG. 17.

In energy levels where electrons are mainly present in the active region 123, there is an upper energy level #7 with a higher electron density than electron densities of lower energy levels #3 and #4. In addition, there is an upper energy level #9 with a higher electron density than the electron densities of the lower energy levels #3 and #4. An actual calculation revealed that the highest gain when a current with a same magnitude is injected is obtained when the upper energy level is #7 and the lower energy level is #4. Therefore, a gain when transitioning between these energy levels will be considered.

There are energy levels #1, #2, and #3 that are lower energy levels than the lower energy level #4. Furthermore, there are energy levels #8, #9, and #10 that are higher energy levels than the higher energy level #7.

As described above, the energy levels and the electron densities shown in FIG. 17 satisfy the three conditions necessary for laser oscillation. Therefore, laser oscillation can occur when an electric field is applied from the second electrode toward the first electrode of the second modification of the QCL device according to the present embodiment.

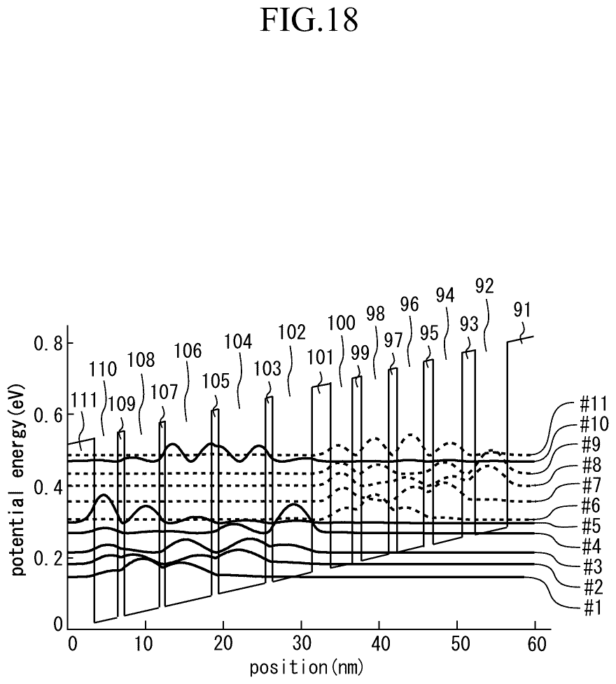

FIG. 18 is a diagram showing an existence probability of electrons when an electric field is applied from the first electrode toward the second electrode of the second modification of the QCL device according to the first embodiment of the present disclosure. FIG. 18 shows a square of a wave function at each energy level in the stage 126. For convenience of calculation, an orientation of each layer has been reversed so that potential energy increases toward the right. In addition, the strength of the applied electric field is 5.0×10⁶ V/m which is the same as in FIGS. 16 and 17.

In this case, there are 11 different energy levels allowed in the stage 84. The 11 energy levels are numbered from #1 to #11, starting with a lowest energy level. In addition, each energy level is shown by a solid line if the electrons are mainly present in the active region 123 and by a dashed line if the electrons are mainly present in the injector region 124. The levels where electrons are mainly present in the active region 123 are #1, #2, #3, #4, #5, and #10. The levels where electrons are mainly present in the injector region 124 are #6, #7, #8, and #9.

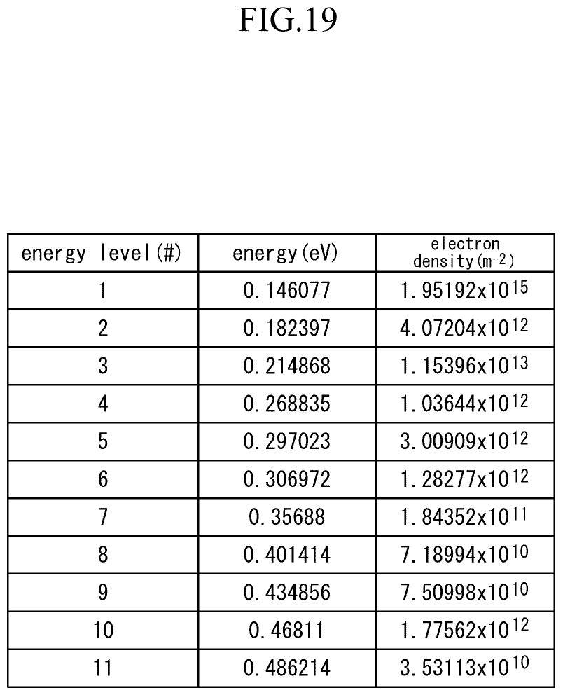

FIG. 19 is a table showing energy levels and electron densities when an electric field is applied from the first electrode toward the second electrode of the second modification of the QCL device according to the first embodiment of the present disclosure.

The three conditions will be confirmed with respect to the energy levels and the electron densities shown in FIG. 19. In energy levels where electrons are mainly present in the active region 123, there is an upper energy level #10 with a higher electron density than an electron density of a lower energy level #4. In addition, there are energy levels #1, #2, and #3 that are lower energy levels than the lower energy level #4. Furthermore, there is an energy level #11 that is a higher energy level than the higher energy level #10.

As described above, the energy levels and the electron densities shown in FIG. 19 satisfy the three conditions necessary for laser oscillation. Therefore, laser oscillation can occur when an electric field is applied from the first electrode toward the second electrode of the second modification of the QCL device according to the present embodiment.

As described above, in the second modification of the QCL device according to the present embodiment, laser oscillation can occur whether current is injected from the first electrode 1 toward the second electrode 9 or from the second electrode 9 toward the first electrode 1. In other words, two different gain bands can be provided by injecting current into the QCL device from two directions.

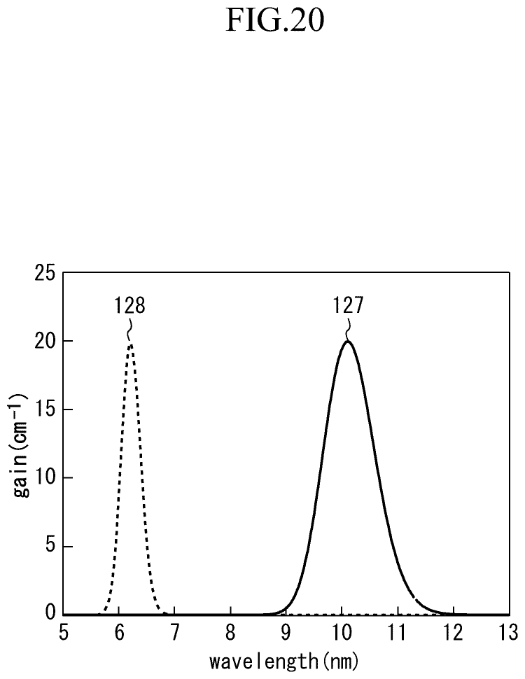

FIG. 20 is a graph showing wavelength dependence of the gain of the first modification of the QCL device according to the first embodiment of the present disclosure. In this case, gains when using an embedded ridge-type QCL device with a resonator length L of 1.36 mm and a ridge width of 14 μm are shown. A gain 127 when an electric field is applied from the second electrode 9 toward the first electrode 1 and a current of 226 mA is injected is shown by a solid line. A gain 128 when an electric field is applied from the first electrode 1 toward the second electrode 9 and a current of 600 mA is injected is shown by a dashed line.

A peak wavelength of the gain 127 is 10.09 μm and a bandwidth at half-maximum is 1.06 μm. On the other hand, a peak wavelength of the gain 128 is 6.21 μm and a bandwidth at half-maximum is 0.40 μm.

As described above, two different gain bands can be provided by injecting current into the QCL device from two directions.

While examples in which the numbers of wells constituting active regions are three, four, and five have been shown in the present embodiment, the number of wells is not limited thereto and other numbers of layers may also be adopted. The same is true for the number of wells in injector regions.

In addition, the value of the injection current is changed in the wavelength dependence of gain in order to unify the values of gain peaks to 20 cm⁻¹. Since laser oscillation occurs when a gain and a loss as a resonator become equal, the injection current may be varied according to a magnitude of the loss.

### Second Embodiment

### Configuration of External Resonance-Type QCL Module Device According to Second Embodiment

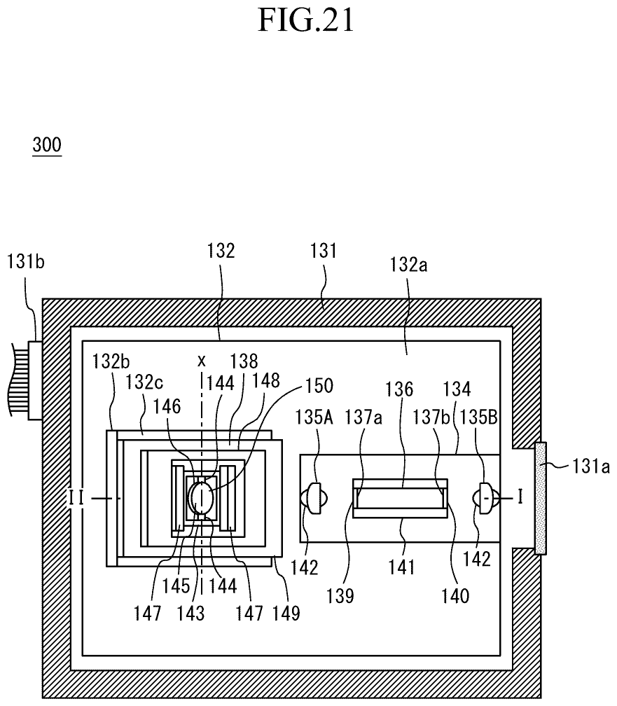

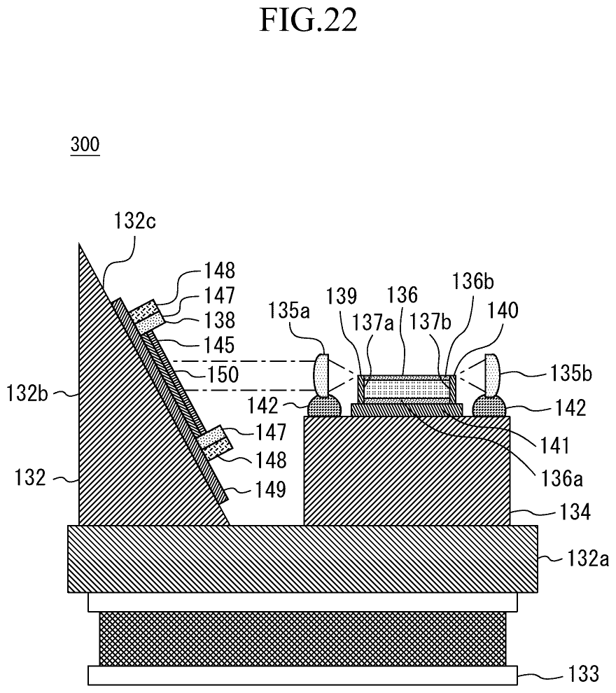

FIG. 21 is a top view showing an external resonance-type QCL module device according to a second embodiment of the present disclosure. An external resonance-type QCL module device 300 according to the present embodiment includes a QCL device 136 according to the first embodiment. In addition, FIG. 22 is a sectional view showing the external resonance-type QCL module device according to the second embodiment of the present disclosure. FIG. 22 is a sectional view showing an aspect of the external resonance-type QCL module device 300 of FIG. 21 cut along I-II.

The external resonance-type QCL module device 300 includes an enclosure 131. The enclosure 131 includes a window 131a for taking out output light to the outside and a drawer 131b for drawing out wiring and the like to the outside.

In addition, the external resonance-type QCL module device 300 includes a base member 132. For example, the base member 132 is made of aluminum (Al) or copper (Cu). The base member 132 includes a side wall section 132b and an inclined surface 132c. A MEMS diffraction grating 138 is fixed on the inclined surface 132c via a mounting member 149. Details of the MEMS diffraction grating 138 will be provided later.

In addition, the base member 132 has a flat bottom section 132a. The bottom section 132a is fixed to a bottom section of the enclosure 131 via a cooler 133. For example, the cooler 133 is a cooling device including a Peltier element. Furthermore, a heat sink 134 is bonded to an upper part of the bottom section 132a. For example, the heat sink 134 is made of a heat-dissipating member such as copper (Cu).

The QCL device 136 is fixed on top of the heat sink 134 via a submount 141. For example, the submount 141 is made of aluminum nitride (AlN) or silicon carbide (SiN).

The QCL device 136 includes a first electrode 136a and a second electrode 136b. In addition, the QCL device 136 includes a first end surface 137a. A reflection reducing section 139 is provided on the first end surface 137a. For example, the reflection reducing section 139 is constituted of an AR (Anti-Reflection) layer with a reflectance of less than 1%.

In addition, the QCL device 136 includes a second end surface 137b. The second end surface 137b opposes the first end surface 137a. A reflection reducing section 140 is provided on the second end surface 137b. For example, the reflection reducing section 140 is constituted of a low reflectance layer with a reflectance of around 10%. The second end surface 137b constitutes an external resonator with the MEMS diffraction grating 138 to be described later.

In addition, lenses 135a and 135b are installed on top of the heat sink 134 via an ultraviolet-curing resin 142. The lenses 135a and 135b are aspherical lenses. The lenses 135a and 135b are made of a material with low absorption of mid-infrared light such as zinc selenide (ZnSe) or germanium (Ge).

The lens 135b is arranged on a side of the second end surface 137b with respect to the QCL device 136. In addition, the lens 135b collimates light emitted from the second end surface 137b. The light collimated by the lens 135b is outputted to the outside through the window 131a.

The lens 135a is arranged on a side of the first end surface 137a with respect to the QCL device 136. In addition, the lens 135a collimates light emitted from the first end surface 137a.

The light collimated by the lens 135a is incident to the MEMS diffraction grating 138. By diffracting and reflecting the incident light, the MEMS diffraction grating 138 causes light of a specific wavelength in the incident light to return to the first end surface 137a. Since the first end surface 137a is provided with the reflection reducing section 139 that is constituted of AR with a reflectance of 1% or less, more than 99% of the light is coupled to the QCL device 136 and directed toward the second end surface 137b. The second end surface 137b is provided with the reflection reducing section 140 that is constituted of a low reflectance layer with a reflectance of around 10%. Therefore, around 90% of the incident light is emitted outside the QCL device 136 and the remaining 10% is reflected and directed toward the first end surface 137a. Accordingly, an external resonator is constructed between the second end surface 137b and the MEMS diffraction grating 138.

A support section 143 included in the MEMS diffraction grating 138 supports a movable section 145 and the like via a pair of coupling sections 144. Each coupling section 144 extends along an axis x. In addition, each coupling section 144 couples the movable section 145 to the support section 143 on the axis x so that the movable section 145 is freely swingable around the axis x.

The movable section 145 is a flat plate-shaped member that is circular in plan view and is positioned inside the support section 143. The movable section 145 is coupled by the support section 143 so as to be freely swingable. The support section 143, the coupling sections 144, and the movable section 145 are integrally formed by, for example, being fabricated on a single SOI (Silicon on Insulator) substrate.

A diffraction reflecting section 150 is provided on a surface of the movable section 145 on a side of the QCL device 136. The diffraction reflecting section 150 includes a diffraction reflecting surface that diffracts and reflects light emitted from the QCL device 136. For example, the diffraction reflecting section 150 is provided over the surface of the movable section 145. In addition, the diffraction reflecting section 150 is constituted of a resin layer on which a diffraction grating pattern is formed and a metal layer. The metal layer is provided over the surface of the resin layer so as to follow the diffraction grating pattern. Alternatively, the diffraction reflecting section 150 may be provided on the movable section 145 and solely constituted of a metal layer on which a diffraction grating pattern is formed. For example, the diffraction grating pattern is a grating with a saw blade-shaped cross-section, a grating with a rectangular cross-section, or a grating with a sinusoidal cross-section.

A coil 146 is embedded in a groove formed on the surface of the movable section 145. The coil 146 is spirally wound a plurality of times in plan view. Wiring for connection to the outside is electrically connected to an outer end and an inner end of the coil 146. For example, the wiring is provided over the support section 143, the coupling sections 144, and the movable section 145 and is electrically connected to electrodes provided on the support section 143.

A magnetic field acting on the coil 146 is generated by a pair of magnets 147. Each of the pair of magnets 147 is formed in a rectangular parallelepiped shape and the pair of magnets 147 is arranged so as to oppose a pair of edges of the support section 143 that is parallel to the axis x. An array of magnetic poles in each magnet 147 is, for example, a Halbach array. A yoke 148 is arranged at a position surrounding the pair of magnets 147 and the support section 143. The yoke 148 has a rectangular frame shape in plan view and amplifies a magnetic force of the magnets 147.

When a current flows through the coil 146, a magnetic field generated by the pair of magnets 147 in the MEMS diffraction grating 138 creates a Coulomb force. The Coulomb force is created in a predetermined direction with respect to electrons flowing in the coil 146. Accordingly, the coil 146 is subjected to a force in the predetermined direction. Therefore, the movable section 145 can be caused to swing by controlling an orientation, a magnitude, or the like of the current flowing in the coil 146. In other words, the diffraction reflecting section 150 can be caused to swing around the axis x. In addition, the movable section 145 can be caused to swing at high speed at a resonant frequency level by passing a current with a frequency corresponding to the resonant frequency of the movable section 145 through the coil 146. In this manner, the coil 146 and the pair of magnets 147 function as an actuator section that causes the movable section 145 to swing.

### Operation of QCL Device According to Second Embodiment

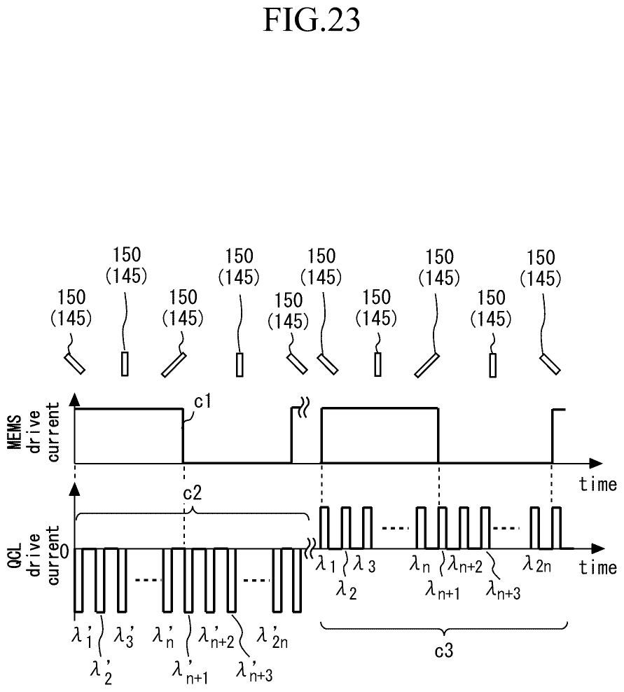

FIG. 23 is a diagram showing a drive method of the MEMS diffraction grating and the QCL device according to the second embodiment of the present disclosure. Here, a method of driving the MEMS diffraction grating and the QCL device for performing a wavelength sweep in two wavelength bands by applying an electric field in two directions will be described.

As described in the first embodiment, a gain band of the QCL device 136 differs between when the electric field is applied from the second electrode 136b toward the first electrode 136a and when the electric field is applied from the first electrode 136a toward the second electrode 136b. In other words, wavelength sweeps in two wavelength bands can be performed by applying an electric field in two directions. Therefore, a drive method when the QCL device 136 shares a same configuration as the QCL device 200 according to the first embodiment will now be described.

In FIG. 23, a top graph shows a current flowing through the MEMS diffraction grating 138 and a bottom graph shows a current flowing through the QCL device 136. An orientation of the diffraction reflecting section 150 or, in other words, an orientation of the movable section 145 that operates the diffraction reflecting section 150 is shown above the graph showing a current flowing through the MEMS diffraction grating 138.

First, a drive current c1 is applied to the MEMS diffraction grating 138 or, in other words, the coil 146. The drive current c1 is a pulsed current of a first frequency f1. Accordingly, the diffraction reflecting section 150 or, in other words, the movable section 145 swings repeatedly at the first frequency. Therefore, a period T1 of the swing of the diffraction reflecting section 150 is 1/f1. In this case, the period T1 is the time required for the diffraction reflecting section 150 to make one round trip. In addition, a wavelength of output light from the external resonance-type QCL module device 300 varies with an angle of rotation of the diffraction reflecting section 150.

At this point, a drive current c2 is first passed from the first electrode 136a to the second electrode 136b in the QCL device 136. In other words, an electric field is applied from the first electrode 136a toward the second electrode 136b. In this case, the drive current c2 is a pulsed current of a second frequency f2 that is a higher frequency than the first frequency. Accordingly, pulsed light of the second frequency f2 is emitted from the QCL device 136. In other words, a waveform of the pulsed light emitted from the QCL device 136 is similar to that of the drive current c2. Therefore, a period T2 of the pulsed light is 1/f2. If a pulse width of the pulsed light is denoted by T3, a duty ratio is T3/T2 which is a value greater than 0% and smaller than around 10%.

FIG. 23 shows the drive current c2 at an initial phase before a phase of the pulsed light is changed as will be described later. In this example, a rising point of the pulse light in the initial phase coincides with a folding point of the diffraction reflecting section 150.

When the QCL device 136 is driven in this manner, pulsed light is emitted from the QCL device 136 n-number of times during an outward period in the swing of the diffraction reflecting section 150 or, in other words, during T1/2. In this case, n is equal to (T1/2)/T2. Since a rotation angle of the diffraction reflecting section 150 differs depending on a timing of each light emission, the wavelength of the emitted light assumes mutually different values λ_{1′}, λ_{2′}, λ_{3′}, . . . , λ_{n′}. For example, when the output light is swept in order from a short wavelength side, λ_{1′}<λ_{2′}<λ_{3′}< . . . <λ_{n′} is satisfied.

On the other hand, pulsed light is also emitted from the QCL device 136 n-number of times during a return return in the swing of the diffraction reflecting section 150. As described above, when the output light is swept in order from the short wavelength side during the outward period, the output light is swept in order from a long wavelength side in the return period which is contrary to the outward period. In other words, at wavelengths λ_{n+1′}, λ_{n+2′}, λ_{n+3′}, . . . , λ₂ₙ of light sequentially emitted from the QCL device 136, λ_{n+1′}>λ_{n+2′}>λ_{n+3′}> . . . >λ₂ₙ is satisfied.

In this case, the wavelengths λ_{n+1′}, λ_{n+2′}, λ_{n+3′}, . . . , λ₂ₙ of the output light during the return period are approximately equal to wavelengths obtained by inverting the wavelengths λ_{1′}, λ_{2′}, λ_{3′}, . . . , λₙ during the outward period with respect to time based on a time point where the outward period and the return period are switched. Therefore, either the outward period or the return period is used in an analyzer to be described later. Due to the above, for example, the QCL device 200 according to the first embodiment is capable of performing a wavelength sweep by a short wavelength-side gain shown in FIGS. 7 and 8.

Next, a drive current c3 is passed from the second electrode 136b toward the first electrode 136a in the QCL device 136. In other words, an electric field is applied from the second electrode 136b toward the first electrode 136a. In this case, the drive current c3 is a pulsed current of a second frequency f2 that is a higher frequency than the first frequency. In addition, the drive current c1 is applied to the MEMS diffraction grating 138 or, in other words, the coil 146. The drive current c1 is a pulsed current of the first frequency f1 which is the same as when a pulsed current is passed from the first electrode 136a to the second electrode 136b. Accordingly, the diffraction reflecting section 150 performs a same operation as the swing described earlier. Therefore, a wavelength of output light varies with an angle of rotation of the diffraction reflecting section 150. In other words, the output light is similar to the case described above with the exception of an orientation and a current value of the current being different.

When the QCL device 136 is driven, pulsed light is emitted from the QCL device 136 n-number of times during an outward period in the swing of the diffraction reflecting section 150 or, in other words, during T1/2. In this case, n is equal to (T1/2)/T2. At this point, the wavelength of the emitted light assumes mutually different values λ_{1′}, λ_{2′}, λ_{3′}, . . . , λ_{n′}. For example, when the output light is swept in order from a short wavelength side, λ_{1′}<λ_{2′}<λ_{3′}< . . . <λ_{n′} is satisfied.

In a similar manner, pulsed light is also emitted from the QCL device 136 n-number of times during a return return in the swing of the diffraction reflecting section 150. As described above, when the output light is swept in order from the short wavelength side during the outward period, the output light is swept in order from a long wavelength side in the return period which is contrary to the outward period. In other words, at wavelengths λ_{n+1′}, λ_{n+2′}, λ_{n+3′}, . . . , λ₂ₙ of light sequentially emitted from the QCL device 136, λ_{n+1′}>λ_{n+2′}>λ_{n+3′}> . . . >λ₂ₙ is satisfied.

In this case, the wavelengths λ_{n+1′}, λ_{n+2′}, λ_{n+3′}, . . . , λ₂ₙ of the output light during the return period are approximately equal to wavelengths obtained by inverting the wavelengths λ_{1′}, λ_{2′}, λ_{3′}, . . . , λₙ during the outward period with respect to time based on a time point where the outward period and the return period are switched. Therefore, either the outward period or the return period is used in an analyzer to be described later. Due to the above, for example, the QCL device 200 according to the first embodiment is capable of performing a wavelength sweep by a long wavelength-side gain shown in FIGS. 7 and 8.

A wavelength range that can be swept by the angle of rotation of the diffraction reflecting section 150 is wider than a gain range obtained by adding a gain range when a current is passed from the second electrode 136b to the first electrode 136a in the QCL device 136 to a gain range when a current is passed from the first electrode 136a to the second electrode 136b in the QCL device 136.

### Modification of External Resonance-Type QCL Module Device According to Second Embodiment

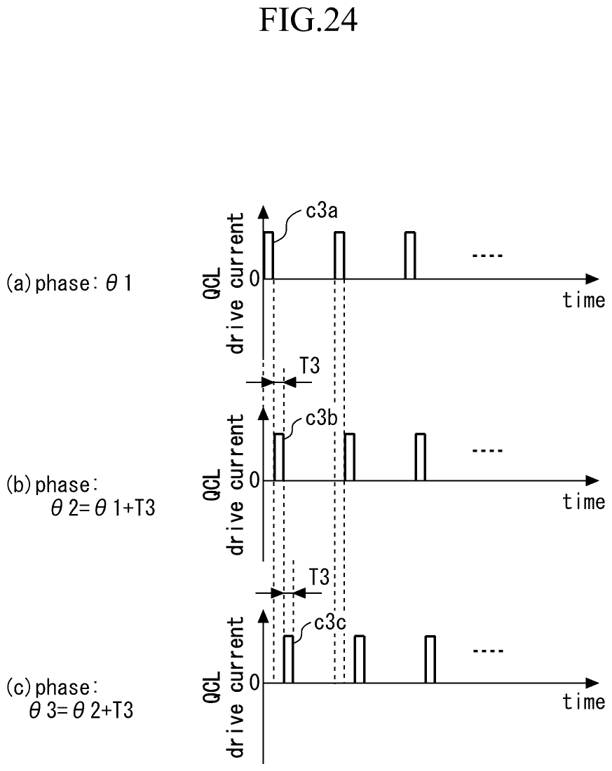

FIG. 24 is a diagram showing a modification of a drive method of the external resonance-type QCL module device according to the second embodiment of the present disclosure. The drive method according to the present modification differs from the second embodiment in that a phase of a drive current is changed for each round trip of the diffraction reflecting section 150.

While a case where a current is passed from the second electrode 136b toward the first electrode 136a or, in other words, an electric field is applied from the second electrode 136b toward the first electrode 136a will be shown here as an example, the same applies when a current is passed from the first electrode 136a toward the second electrode 136b.

In the present modification, by changing a phase of a current that drives the QCL device 136 by T3 every time the diffraction reflecting section 150 makes a round trip, a phase of emitted pulsed light is changed by a pulse width of T3. For example, let us suppose that the phase of a first drive current c3a is θ1. A phase θ2 of a drive current c3b after one round trip of the diffraction reflecting section 150 is θ+T3. A phase θ3 of a drive current c3c after another round trip of the diffraction reflecting section 150 is θ2+T3.

Accordingly, the phase of the drive current is shifted by a pulse width of T3 each time the diffraction reflecting section 150 makes one round trip. In doing so, the phase of the pulsed light emitted from the QCL device 136 also changes by a pulse width of T3 as the phase of the drive current changes. This phase change is repeated p−1-number of times, where p=T2/T3. Accordingly, since a wavelength spectrum of output light on a time axis is filled without gaps, an apparently continuous wavelength sweep is achieved.

### Third Embodiment

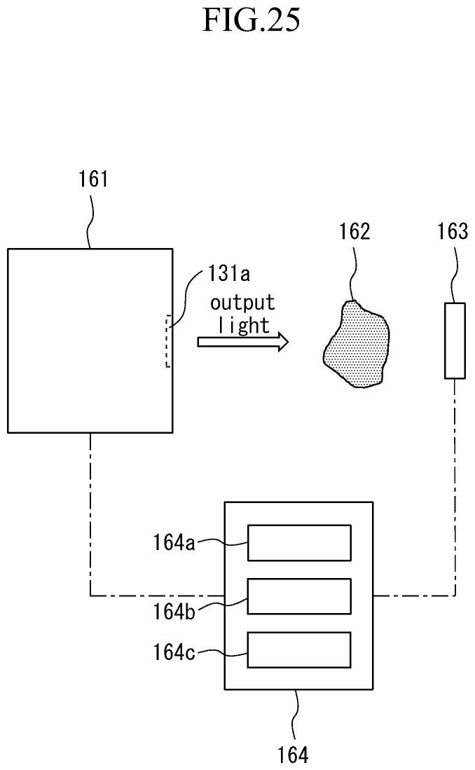

FIG. 25 is a diagram showing an analyzer according to a third embodiment of the present disclosure. The analyzer according to the present embodiment is a device that includes an external resonance-type QCL module device 161 according to the second embodiment and that performs spectroscopic analysis by measuring an absorption spectrum of an analyte 162.

The external resonance-type QCL module device 161 irradiates the analyte 162 with output light emitted from the window 131a. The analyte 162 may be any of a gas, a liquid, or a solid.

The absorption spectrum of the analyte 162 is detected by a photodetector 163. The photodetector 163 is, for example, a mercury cadmium telluride (MCT) detector, an indium arsenic antimony (InAsSb) photodiode, or a thermopile.

A detection result of the photodetector 163 is transmitted to a controller 164. The controller 164 calculates an absorption spectrum based on the detection result. In addition, the controller 164 is electrically connected to, and controls, the external resonance-type QCL module device 161 and the photodetector 163.

The controller 164 includes a diffraction grating control unit 164a. The diffraction grating control unit 164a controls drive of the MEMS diffraction grating 138. In addition, the controller 164 includes a QCL device control unit 164b. The QCL device control unit 164b controls drive of the QCL device 136. Furthermore, the controller 164 includes a computing unit 164c. The computing unit 164c calculates an absorption spectrum based on the detection result of the photodetector 163.

In addition, the controller 164 may be constituted of a computer including an arithmetic circuit such as a CPU (Central Processing Unit) in which arithmetic processing is performed, a recording medium constituted of a memory such as a RAM (Random Access Memory) and a ROM (Read Only Memory), and an input/output device. Furthermore, the controller 164 operates by loading a computer program or the like.

While an aspect in which Ga_{0.47}In_{0.53}As as a well layer and Al_{0.48}In_{0.52}As as a barrier layer are latticed-matched with InP has been shown in the embodiments of the present disclosure, the present disclosure is not limited to this aspect. For example, a compressive or tensile strain may be written on the well layer or the barrier layer.

While an aspect of an InP-based QCL device using an InP substrate has been shown in the embodiments of the present disclosure, the present disclosure is not limited to this aspect. For example, the QCL device may be a GaAs-based QCL device with a GaAs well layer and an AlGaAs barrier layer using a GaAs substrate. Alternatively, the QCL device may be a GaN-based QCL device with a GaN well layer and an AlGaN barrier layer using a GaN substrate.

In addition, while an aspect in which a doping concentration of an injector region is set to 2.5×10¹⁷ cm⁻³ has been shown in the embodiments of the present disclosure, the present disclosure is not limited to this aspect. A higher doping concentration enables a gain band to be broadened. A lower doping concentration narrows the gain band but increases a value of a gain peak, thereby lowering a threshold current. Layers to be doped can also be set arbitrarily.

Furthermore, while an aspect in which the QCL device has a resonator length of 1.36 mm and a ridge width of 14 μm has been shown in the embodiments of the present disclosure, other resonator lengths and ridge widths may be adopted. In addition, a structure of the QCL device is also not limited to an embedded ridge-type. For example, the structure may be a current constriction structure due to ion implantation of protons or the like or a current constriction structure due to an insulating film.

### REFERENCE SIGNS LIST

1 first electrode, 5 core region, 9 second electrode, 11, 13, 15, 17, 19, 21, 23, 25, 27, 29, 31, 33, 35, 37 barrier layer, 12, 14, 16, 18, 20, 22, 24, 26, 28, 30, 32, 34, 36 well layer, 38 injector region, 39 active region, 40 injector region, 41, 42 stage, 51, 53, 55, 57, 59, 61, 63, 65, 67, 69, 71, 73, 75, 77, 79 barrier layer, 52, 54, 56, 58, 60, 62, 64, 66, 68, 70, 72, 74, 76, 78 well layer, 80 injector region, 81 active region, 82 injector region, 83, 84 stage, 91, 93, 95, 97, 99, 101, 103, 105, 107, 109, 111, 113, 115, 117, 119, 121 barrier layer, 92 94, 96, 98, 100, 102, 104, 106, 108, 110, 112, 114, 116, 118, 120 well layer, 122 injector region, 123 active region, 124 injector region, 125, 126 stage, 136a first electrode, 136b second electrode, 150 diffraction reflecting section, 163 photodetector, 164c computing unit

1. A QCL device, comprising a first electrode, a second electrode, and a core region which is formed between the first electrode and the second electrode and which has a plurality of stages, wherein
each stage includes:
an active region in which a plurality of alternating barrier layers and well layers are formed and which emits light; and
an injector region in which a plurality of alternating barrier layers and well layers are formed and which injects electrons into the active region,
when an electric field is applied from the second electrode to the first electrode, a first subband group is formed in the stage,
the first subband group includes a first subband, a second subband, a third subband, and a fourth subband, each subband is configured so that
the first subband and the second subband have electrons predominantly in the active region,
the second subband has a higher energy level and a higher electron density than the first subband,
light emits when electrons transition from the second subband to the first subband,
the third subband has a lower energy level than the first subband,
the fourth subband has a higher energy level than the second subband,
when an electric field is applied from the first electrode to the second electrode, a second subband group is formed in the stage,
the second subband group includes a fifth subband, a sixth subband, a seventh subband, and an eighth subband, each subband is configured so that
the fifth subband and the sixth subband have electrons predominantly in the active region,
the sixth subband has a higher energy level and a higher electron density than the fifth subband,
light emits when electrons transition from the sixth subband to the fifth subband,
the seventh subband has a lower energy level than the fifth subband, and
the eighth subband has a higher energy level than the sixth subband.

2. An external resonance-type QCL module device, comprising
the QCL device according to claim 1 and a MEMS diffraction grating, wherein
the MEMS diffraction grating
includes a diffraction reflecting section which diffracts and reflects light emitted from the QCL device, and
returns a part of the light back to the QCL device by swinging the diffraction reflecting section.

3. An analyzer, comprising:
the external resonance-type QCL module device according to claim 2;
a photodetector which detects light emitted from the external resonance-type QCL module device and transmitted through an analyte; and
a computing circuitry which calculates an absorption spectrum based on a detection result of the photodetector.

4. A light irradiation method using the QCL device according to claim 1, the light irradiation method comprising:
emitting light of a first frequency band by applying an electric field from the second electrode toward the first electrode; and
emitting light of a second frequency band by applying an electric field from the first electrode toward the second electrode.
